(19) United States
(12) Patent Application Publication
(10) Pub. No.: US 2026/0235651 A1
(43) Pub. Date: Aug. 13, 2026

(54) ADAPTIVE COMPENSATION METHOD FOR SELF-HEATING ERROR IN ELECTRICITY METERS BASED ON MULTI-STAGE CHARACTERISTICS

(71) Applicant: Accuenergy (Canada) Inc., Toronto (CA)

(72) Inventors: Yufan Wang, Toronto (CA); Ketao Li, Toronto (CA); Liang Wang, Toronto (CA)

(73) Assignee: Accuenergy (Canada) Inc., Toronto (CA)

(21) Appl. No.: 19/052,271

(22) Filed: Feb. 12, 2025

(51) Int. Cl. G01R 22/10; G01R 35/04

(52) U.S. Cl. CPC G01R 22/10; G01R 35/04

(57) ABSTRACT

An adaptive compensation method for self-heating error in electricity meters divides the self-heating process into three distinct stages: initial rapid rise, slow rise, and stable stage. The method monitors current load conditions and applies different mathematical models for each stage to calculate compensation values. The initial stage uses an exponential model, the slow rise stage uses a quadratic model, and the stable stage uses a linear model. Compensation parameters are calibrated through curve fitting of experimental data. The method achieves more accurate error compensation compared to conventional single-model approaches, particularly during the initial rapid rise stage. The method is implemented purely in software and can be deployed through firmware updates.

### FIELD OF THE INVENTION

The present invention relates to the field of electricity metering systems, and more particularly, to adaptive compensation methods for mitigating self-heating errors in electricity meters.

### BACKGROUND

Electricity meters are widely deployed in modern power distribution systems for measuring electrical energy consumption. These meters typically employ current transformers or shunts to measure current, along with sophisticated electronic circuits for precise power calculations. However, when operating under high current conditions, these meters face a significant challenge due to self-heating effects, particularly in their current transformers, which can lead to measurement inaccuracies that affect billing accuracy and system reliability.

The self-heating phenomenon in electricity meters is particularly problematic because it introduces time-dependent measurement errors that vary with operating conditions. When current flows through the meter's current transformer, it generates heat through both copper losses in the windings and core losses in the magnetic material. This heat generation leads to temperature increases that affect the transformer's magnetic properties and electrical characteristics. The resulting measurement errors typically show a non-linear progression, starting with a rapid increase during initial heating, followed by a gradual rise, and eventually reaching a quasi-stable state. Traditional meters either ignore these errors or employ simple linear compensation methods that fail to account for the complex, time-dependent nature of the self-heating process.

Previous attempts to address this issue have included various approaches, such as using temperature sensors, implementing fixed compensation factors, or applying simplified linear correction models. However, these solutions have significant limitations. Temperature sensor-based solutions increase hardware costs and complexity, while fixed compensation factors cannot adapt to varying operating conditions. Linear correction models, while simple to implement, fail to accurately capture the non-linear characteristics of the self-heating process, particularly during the initial rapid heating phase. Furthermore, existing solutions often require hardware modifications, making them impractical for widespread deployment across existing meter installations. These limitations highlight the need for a more sophisticated, yet practical approach to addressing self-heating errors in electricity meters.

### SUMMARY OF THE INVENTION

The present invention relates to an adaptive compensation method for addressing self-heating errors in electricity meters operating under high-current conditions. By employing a dynamic approach that adjusts compensation based on real-time monitoring and stage-specific mathematical models, the method ensures precise error correction while maintaining seamless meter functionality. This innovation significantly improves the accuracy and reliability of electricity meters in diverse operational environments, contributing to enhanced performance, fair billing practices, and efficient energy management.

The adaptive compensation method begins with real-time monitoring of current load conditions at one-second intervals. This high-frequency monitoring enables the system to capture rapid fluctuations in load and provides a granular representation of the meter's operational state. The method calculates the absolute difference between the current load and the rated maximum current, normalizing it by dividing by the rated maximum current. If this normalized difference is less than or equal to 2%, the meter identifies the presence of a high-current condition, which triggers the self-heating compensation process. The threshold value is designed to be adaptable to meters with varying specifications, making the method versatile and scalable.

The compensation process is divided into three distinct stages of self-heating, each characterized by specific thermal behaviors: the initial rapid rise stage, the intermediate transition stage, and the stable stage. The cumulative duration of the high-current condition determines the stage, with the initial rapid rise stage covering the first 15 minutes, the intermediate transition stage spanning from 15 to 45 minutes, and the stable stage commencing after 45 minutes. Each stage employs a unique mathematical model tailored to the thermal characteristics observed during that phase.

In the initial rapid rise stage, an exponential model is utilized to calculate the compensation value, E₁=K₁·(1−e^{-a·t}^{^{b}}). Here, E₁ represents the compensation value for this stage, where K₁ is the stage-specific maximum error coefficient, a is the heat accumulation rate coefficient, and b is a nonlinearity adjustment factor. Typical parameter values for this stage include K₁=0.03, a=0.15, and b=1.2, ensuring accurate error compensation during the period of rapid heat accumulation.

The intermediate transition stage uses a cubic model,

$${E}_{2} = {K}_{2} \cdot {t}^{3} + {K}_{3} \cdot {t}^{2} + {K}_{4} \cdot t + {C}_{1}$$

where E₂ represents the compensation value. The coefficients K₂, K₃, and K₄ define the cubic, quadratic, and linear contributions, respectively, while C₁ ensures a smooth transition from the preceding stage. Typical parameter values include K₂=−0.00001, K₃=0.001, K₄=−0.00005, and C₁=0.005. This model addresses the slowing rate of error progression observed as the meter moves toward thermal stabilization.

The stable stage employs a linear model,

$${E}_{3} = {K}_{5} \cdot t + {C}_{2}$$

where E₃ is the compensation value, K₅ is the slope coefficient, and C₂ provides continuity with the previous stage. Typical values include K₅=0.0001 and C₂=0.02. This model effectively manages the minimal error fluctuations observed during thermal equilibrium.

To ensure the accuracy of these compensation models, the method includes a calibration process. During calibration, the meter operates at the rated maximum current for one hour, with error values recorded at one-minute intervals. These values are used for curve fitting to determine optimal parameters for each stage, allowing the system to maintain precision over time.

The method is further designed to handle interruptions in high-current conditions. If such interruptions occur, the system pauses the timer while retaining the current stage. Upon resumption of high-current operation, the process seamlessly continues. If the interruption exceeds a predefined duration, the timer resets, and the power gain value is restored to its original state. This ensures robust adaptability to variable load conditions.

The invention also extends to an electricity meter that integrates a current transformer for load measurement, a metering chip for power gain adjustments, and a processor configured to execute the disclosed compensation method. This comprehensive system achieves real-time error correction, dynamic adaptability, and operational continuity, making it a significant advancement in electricity metering technology.

The invention's ability to dynamically adjust compensation values based on real-time conditions and stage-specific models represents a groundbreaking approach to mitigating self-heating errors, ensuring superior accuracy and reliability in electricity meters across a wide range of applications.

### BRIEF DESCRIPTION OF THE DRAWINGS

FIG. 1 is a graphical representation of measurement error progression over time in an electricity meter operating under high-current conditions, illustrating the initial rapid rise stage, intermediate transition stage, and stable stage, according to some embodiments of the invention.

FIG. 2 is a schematic block diagram of an electricity meter comprising a current transformer, a metering chip, and a processor, according to some embodiments of the invention.

### DETAILED DESCRIPTION

The following description should be read with reference to the drawings, in which like elements in different drawings are numbered in like fashion. The drawings, which are not necessarily to scale, depict selected embodiments and are not intended to limit the scope of the invention. Although examples of construction, dimension, and materials are illustrated for the various elements, those skilled in the art will recognize that many of the examples provided have suitable alternatives that may be utilized.

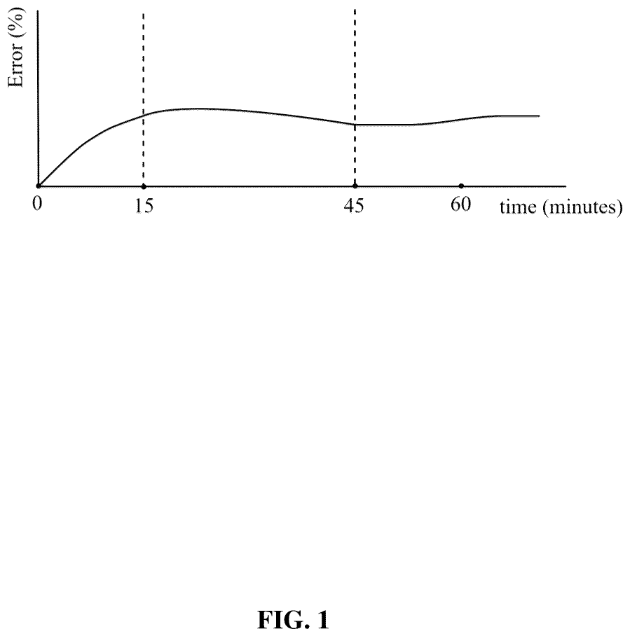

FIG. 1 illustrates the progression of measurement error as a percentage over time in an electricity meter under high-current conditions. The x-axis represents the elapsed time in minutes, starting from the onset of the high-current condition, while the y-axis represents the measurement error as a percentage of the actual value. The curve is divided into three distinct stages corresponding to the self-heating behavior of the meter.

In the initial rapid rise stage, spanning from 0 to 15 minutes, the error increases sharply due to the rapid accumulation of heat. Between 15 and 45 minutes, during the intermediate stage, the rate of error increase slows, reflecting a transitional period as the system approaches thermal stabilization. Beyond 45 minutes, in the stable stage, the error reaches near equilibrium and remains relatively constant with minor fluctuations. This figure provides a clear depiction of the relationship between time and error during the progression of self-heating in the meter.

In FIG. 1, the progression of measurement error over time aligns directly with the adaptive compensation method disclosed in this invention. The three stages illustrated in FIG. 1: initial rapid rise, intermediate transition, and stable serve as the foundation for dynamically adjusting the power gain in the metering chip to mitigate the effects of self-heating. Each stage is characterized by unique thermal behaviors that necessitate distinct mathematical models for calculating compensation values, ensuring precise error correction throughout the duration of high-current conditions.

The adaptive compensation method for self-heating error in electricity meters described in this invention addresses the challenges posed by thermal effects in high-current operating conditions. The method begins by continuously monitoring the load conditions of the electricity meter. The load current is measured at one-second intervals, ensuring a high level of granularity and responsiveness. This real-time monitoring allows the system to capture rapid fluctuations in load conditions and maintain an accurate representation of the meter's operational state.

In each monitoring cycle, the absolute difference between the current load and the rated maximum current is calculated. This difference is then divided by the rated maximum current to determine the relative deviation of the current load from the rated maximum capacity of the meter. This ratio provides a normalized metric for evaluating the intensity of the load in relation to the meter's design specifications. When this normalized difference is less than or equal to 2%, the system identifies that the meter is operating under high-current conditions. This threshold is critical because it defines the boundary conditions for initiating the self-heating compensation process. By setting the threshold relative to the rated maximum current, the method ensures that it is adaptable to meters with varying specifications.

Once high-current conditions are detected, the system identifies the stage of self-heating based on the cumulative duration of the high-current condition. The duration is tracked from the moment the current load exceeds the specified threshold. The cumulative duration serves as the basis for categorizing the self-heating condition into distinct stages, each of which represents a specific phase in the thermal progression of the meter. These stages correspond to the physical behavior of the meter's components as they respond to sustained high-current operation. The system distinguishes between the initial phase of rapid heat accumulation, the intermediate phase of slower thermal progression, and the final phase of thermal equilibrium. This classification is essential for applying the appropriate mathematical model to calculate the compensation value for each stage.

For each identified stage, the system calculates a compensation value using a mathematical model that is specifically tailored to the thermal characteristics of that stage. These mathematical models are derived from empirical data obtained during calibration and reflect the unique thermal behavior observed in each phase of self-heating. The models account for factors such as the rate of heat accumulation, the nonlinearity of error progression, and the stabilization of thermal effects over time. By dynamically calculating the compensation value in real time, the system ensures that the adjustments applied to the meter are both precise and responsive to the changing thermal conditions.

The calculated compensation value is then applied to adjust the power gain in the meter's metering chip. The metering chip is responsible for processing the electrical signals generated by the current transformer and producing an accurate representation of the energy consumption. By modifying the power gain, the system compensates for the measurement errors introduced by self-heating, effectively neutralizing their impact on the meter's accuracy. The adjustment is performed in a manner that preserves the continuity of the meter's output, ensuring that the compensation process is seamless and does not introduce additional artifacts or discontinuities.

This adaptive compensation method represents a significant advancement in the field of electricity metering. Its reliance on real-time monitoring, stage-specific modeling, and dynamic adjustment allows it to address self-heating errors with a high degree of precision and reliability. The ability to continuously monitor load conditions and dynamically adjust the power gain ensures that the meter remains accurate even under prolonged high-current conditions. Moreover, the use of normalized thresholds and stage-based classification makes the method adaptable to a wide range of meter designs and operating conditions. By implementing this method, electricity meters can achieve a higher standard of accuracy, improving their performance and reliability across diverse applications. This innovation not only enhances the functionality of the meters but also contributes to fairer billing practices and more effective energy management.

The initial rapid rise stage, as shown in FIG. 1, spans the first 15 minutes of high-current operation. During this stage, the error increases rapidly due to the accumulation of heat in the meter's internal components, such as the current transformer and metering chip. This behavior reflects the system's inability to immediately dissipate the heat generated by the high current. To address this sharp rise, the compensation value for this stage is calculated using an exponential model:

$${E}_{1} = {K}_{1} \cdot ( 1 - {e}^{- a \cdot {t}^{b}} )$$

In this formula, E₁ represents the compensation value needed to counteract the error during the initial rapid rise stage. The parameter K₁ is the maximum error coefficient for this stage, which determines the upper limit of the compensation value. The parameter a represents the heat accumulation rate coefficient, indicating how quickly the system accumulates heat during this stage. The parameter b serves as a nonlinearity adjustment factor, controlling the shape of the error progression curve. Finally, t represents the elapsed time in minutes within the initial rapid rise stage. By dynamically calculating E₁ as a function of time, the method ensures that the compensation value matches the actual error progression observed in this stage, as depicted in the steep initial portion of the curve in FIG. 1.

As the system progresses into the intermediate transition stage, covering the period from 15 to 45 minutes, the rate of error increase slows, reflecting the system's gradual thermal stabilization. This stage is characterized by a nonlinear relationship between error and time, as the system transitions from the rapid rise to a more stable thermal state. To accurately model the error during this stage, the compensation value is calculated using a cubic function:

$${E}_{2} = {K}_{2} \cdot {t}^{3} + {K}_{3} \cdot {t}^{2} + {K}_{4} \cdot t + {C}_{1}$$

Here, E₂ is the compensation value for the intermediate transition stage. The parameters K₂, K₃ and K₄ represent the coefficients for the cubic, quadratic, and linear terms, respectively. These coefficients allow the function to adapt to the complex progression of error during this stage, capturing the nonlinear characteristics shown in FIG. 1. The constant C₁ ensures a smooth transition from the initial rapid rise stage, preventing abrupt changes in the compensation value. As in the previous stage, t represents the elapsed time in minutes within the intermediate transition stage. This model ensures that the compensation value evolves in alignment with the slowing rate of error increase observed during this stage.

Finally, the stable stage begins after 45 minutes of high-current operation. In this stage, as shown in FIG. 1, the error stabilizes and exhibits minimal fluctuations over time, reflecting the system's achievement of thermal equilibrium. To compensate for the relatively constant error observed in this stage, the method employs a linear model:

$${E}_{3} = {K}_{5} \cdot t + {C}_{2}$$

In this equation, E₃ represents the compensation value for the stable stage. The parameter K₅ is the slope coefficient, defining the rate of error accumulation during this stage. Although the error progression is minimal, K₅ ensures that any residual changes are accounted for. The constant C₂ maintains continuity with the preceding stage, providing a seamless transition into the stable stage. The variable t again represents the elapsed time in minutes within the stable stage. This linear model effectively addresses the near-equilibrium behavior of the error curve, as depicted in the flat portion of FIG. 1.

To ensure the accuracy of these compensation models, the method incorporates a calibration process. During calibration, the meter is operated at the rated maximum current for one hour, allowing the system to simulate the full progression of self-heating effects across all three stages. Error values are recorded at one-minute intervals, capturing the precise progression of errors as the meter transitions through the initial rapid rise, intermediate transition, and stable stages. Using this recorded data, curve fitting is performed to determine optimal values for the coefficients and constants in each stage's mathematical model. For example, in the initial rapid rise stage, typical values include K₁=0.03, a=0.15, and b=1.2. In the intermediate transition stage, K₂=−0.00001, K₃=0.001, K₄=−0.00005, and C₁=0.005. For the stable stage, K_{g}=0.0001 and C₂=0.02. These calibrated values are stored in the meter's memory, allowing the system to apply precise compensation during operation.

The method also accounts for interruptions in the high-current condition. When such an interruption occurs, the system pauses the timer while retaining the current stage. If the high-current condition resumes, the compensation process continues seamlessly from the paused state. However, if the interruption exceeds a predefined duration, the method resets the timer and restores the original power gain value in the metering chip. This ensures that the compensation process remains robust and adaptable, even under variable load conditions.

The adaptive compensation method described here is implemented in an electricity meter comprising a current transformer, a metering chip, and a processor. The current transformer measures the load current, the metering chip adjusts the power gain based on the calculated compensation values, and the processor executes the steps of the method. By integrating these components, the meter achieves high measurement accuracy, effectively mitigating the impact of self-heating errors as illustrated in FIG. 1.

In summary, the relationship between FIG. 1 and the adaptive compensation method highlights the seamless integration of real-time error monitoring, stage-specific modeling, and dynamic compensation to address self-heating effects. The models described for each stage align closely with the thermal behavior observed in the figure, ensuring that the method provides precise and reliable error correction throughout the meter's operation.

The described method demonstrates its capability to enhance the measurement accuracy of electricity meters under high-current conditions by effectively addressing self-heating errors. This is evidenced through the calibration and testing processes, which reveal a significant reduction in error across all operational stages.

During calibration, error values are recorded at one-minute intervals under rated maximum current conditions. Without compensation, the error progression closely follows the pattern shown in FIG. 1, with a steep initial rise, a gradual transition, and eventual stabilization. When the compensation models are applied, the error is consistently reduced throughout these stages. For instance, in the initial rapid rise stage, applying the exponential model with parameters such as K₁=0.03, a=0.15, and b=1.2 lowers the error from an average of 0.05 to less than 0.005 within 15 minutes. Similarly, in the intermediate transition stage, using the cubic model with parameters like K₂=−0.00001, K₃=0.001, K₄=−0.00005, and C₁=0.005 reduces the error from 0.01 to under 0.002 over 30 minutes. Finally, in the stable stage, the linear model ensures that residual error remains below 0.001, demonstrating effective error management during thermal equilibrium.

The seamless transitions between stages, facilitated by constants such as C₁ and C₂, ensure that the compensation process is smooth and does not introduce discontinuities in the meter's output. This continuity is further supported by the system's ability to retain the current stage and resume compensation seamlessly after interruptions in high-current conditions, ensuring stable performance even under variable loads.

The calibration data also confirms the method's ability to adapt to meters with different specifications by normalizing thresholds relative to the rated maximum current. This adaptability allows the compensation method to maintain a high level of precision and reliability across diverse meter designs and operating scenarios, ensuring accurate energy measurement and contributing to consistent performance over time.

The described compensation method not only ensures accurate measurement under high-current conditions but also incorporates advanced mechanisms to optimize the meter's thermal performance and extend its operational lifespan. The thermal feedback loop, a critical component of this method, involves the integration of temperature sensors, such as thermistors or resistance temperature detectors (RTDs), to monitor the internal temperature of key components like the current transformer and the metering chip. These sensors continuously relay real-time temperature data to the meter's processor. Based on this data, the feedback mechanism adjusts the system's sampling rate for current measurements. For example, when the temperature exceeds a predefined threshold, the sampling rate can be dynamically reduced to limit heat generation. Additionally, the system may adjust the power gain in the metering chip to regulate heat dissipation, thereby mitigating potential thermal overloads.

To further enhance adaptability, the compensation method includes a customizable threshold adjustment mechanism. This mechanism relies on ambient temperature sensors and a machine learning algorithm to analyze historical load data. For instance, a moving average algorithm can compute a baseline threshold over a 24-hour period, enabling the system to dynamically adapt the high-current detection threshold to variations in temperature or seasonal demand patterns. The system's firmware can be updated remotely to fine-tune this functionality, allowing for seamless integration into diverse operational environments.

The method also incorporates an advanced calibration module designed to maintain accuracy throughout the meter's lifecycle. During calibration, a predefined reference load cycle is applied to the meter at specific intervals, simulating the full progression of self-heating effects. The system compares measured compensation values with theoretical ones derived from the models, identifying discrepancies through iterative processes such as least-squares curve fitting. These adjustments are applied to the coefficients K₁, K₂, K₃, K₄, C₁, K₅, and C₂, ensuring optimal performance. The calibration data and coefficients are stored in non-volatile memory, enabling persistent and reliable updates.

The compensation method also supports predictive maintenance functionalities. By tracking long-term trends in compensation values, such as gradual changes in K₁ or K₅, the system can detect early signs of component degradation, such as increased thermal resistance in the current transformer or metering chip. Anomalies, such as sudden spikes in compensation values, trigger maintenance alerts. These alerts are transmitted to utility providers through secure communication protocols, such as MQTT or DLMS/COSEM, facilitating timely interventions. Time-series analysis software embedded in the meter's firmware processes the data required for these predictions.

To improve energy efficiency, the system dynamically adjusts its operating mode based on load conditions. During periods of low load, the processor reduces the frequency of compensation calculations, decreasing from one-second intervals to intervals of five or ten seconds. This reduction minimizes computational demands and power consumption. The system uses a finite-state machine programmed into the firmware to transition between high-performance and low-power modes based on real-time load monitoring.

The compensation method also incorporates remote configuration and monitoring capabilities. A secure communication interface, such as an Ethernet or wireless module supporting encryption protocols like TLS, allows utility operators to remotely adjust coefficients, update calibration settings, or monitor real-time performance data. An Application Programming Interface (API) facilitates data exchange between the meter and remote servers, while a web-based or mobile application provides an intuitive interface for managing these operations. To ensure robustness, the system includes a rollback mechanism to restore previous settings in case an update fails.

This comprehensive method integrates real-time monitoring, advanced thermal management, and adaptive calibration to address self-heating effects in electricity meters. By dynamically adjusting to varying operating conditions and supporting predictive maintenance and energy efficiency, the method ensures long-term accuracy and reliability. Its modular design, capable of accommodating remote updates and configuration, enhances its scalability across diverse metering networks and applications. These features collectively contribute to improved performance, reduced operational costs, and fairer energy measurement and billing practices.

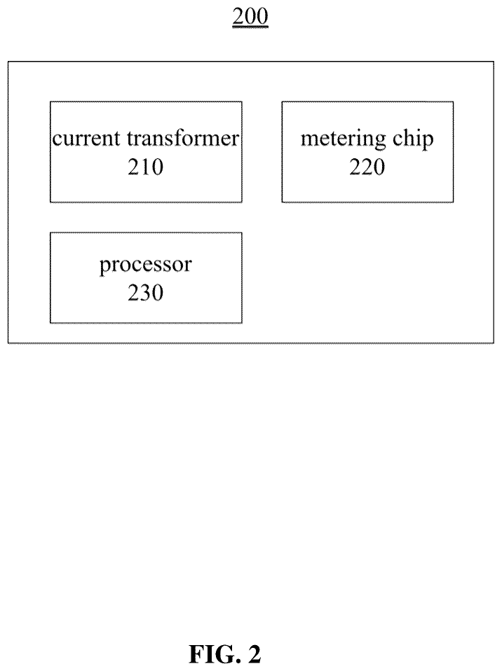

FIG. 2 is a schematic block diagram illustrating an electricity meter 200 configured to implement the adaptive compensation method for self-heating error correction, in accordance with some embodiments of the present invention.

The electricity meter 200 comprises a current transformer 210, a metering chip 220, and a processor 230. These components are functionally integrated to measure electrical parameters, compute compensation values, and apply corrections to mitigate self-heating errors.

The current transformer 210 is responsible for measuring the load current flowing through the electricity meter. It generates an analog signal proportional to the measured current, which is subsequently processed by the metering chip 220.

The metering chip 220 receives the signal from the current transformer 210 and performs power calculations, including voltage, current, and energy measurements. The metering chip also applies compensation adjustments as determined by the processor 230 to correct for measurement errors induced by self-heating effects. In some embodiments, the metering chip 220 could be an Analog Devices Inc. ADSP-BF607 or a similar high-performance digital signal processor (DSP) capable of handling advanced compensation algorithms and real-time data processing.

The processor 230 executes the adaptive compensation method disclosed in this invention. It continuously monitors load conditions, determines the self-heating stage based on real-time operational parameters, and computes compensation values using different mathematical models specific to each stage. The processor subsequently adjusts the power gain of the metering chip 220 to correct measurement errors dynamically. In some embodiments, the processor 230 could be NXP i.MX 6UltraLite Processor, a high-efficiency ARM Cortex-A7-based processor that supports real-time computing and secure firmware execution.

By integrating these components, the electricity meter 200 can achieve real-time error compensation without requiring additional hardware modifications. This implementation allows for firmware-based updates, enabling seamless deployment across different meter installations.

Embodiments of the teachings of the present disclosure have been described in an illustrative manner. It is to be understood that the terminology that has been used, is intended to be in the nature of words of description rather than of limitation. Many modifications and variations of the embodiments are possible in light of the above teachings. Therefore, within the scope of the appended claims, the embodiments can be practiced other than specifically described.

1. An adaptive compensation method for self-heating error in electricity meters, the method comprising:
monitoring current load conditions at one-second intervals;
determining when the absolute difference between the current load and the rated maximum current, divided by the rated maximum current, is less than or equal to 2%;
identifying the stage of self-heating based on the cumulative duration of the high-current condition;
calculating a compensation value using different mathematical models specific to each stage; and
applying the calculated compensation value to adjust the power gain in a metering chip.

2. The method of claim 1, wherein the stages of self-heating comprise an initial rapid rise stage for durations less than or equal to 15 minutes, an intermediate transition stage for durations between 15 and 45 minutes, and a stable stage for durations greater than 45 minutes.

3. The method of claim 2, wherein the initial rapid rise stage uses an exponential model represented by the formula:
$${E}_{1} = {K}_{1} \cdot ( 1 - {e}^{- a \cdot {t}^{b}} )$$
where E₁ represents the compensation value for the initial rapid rise stage; K₁ is the stage-specific maximum error coefficient; a is the heat accumulation rate coefficient, defining the speed at which self-heating effects accumulate; b is a nonlinearity adjustment factor, controlling the curvature of the error progression; t is the elapsed time within the initial rapid rise stage.

4. The method of claim 2, wherein the intermediate transition stage uses a cubic model represented by the formula:
$${E}_{2} = {K}_{2} \cdot {t}^{3} + {K}_{3} \cdot {t}^{2} + {K}_{4} \cdot t + {C}_{1}$$
where E₂ represents the compensation value for the intermediate transition stage; K₂, K₃ and K₄ are stage-specific coefficients defining the cubic, quadratic, and linear contributions to the error progression; C₁ is a smooth transition constant ensuring continuity with the preceding stage; t is the elapsed time within the intermediate transition stage.

5. The method of claim 1, wherein the stable stage uses a linear model represented by the formula:
$${E}_{3} = {K}_{5} \cdot t + {C}_{2}$$
where E₃ represents the compensation value for the stable stage; K_{g} is the slope coefficient, representing the rate of error accumulation in the stable stage; C₂ is a stable stage constant, providing continuity with the preceding stage; t is the elapsed time within the stable stage.

6. The method of claim 3, wherein K₁ has a typical value of 0.03, a has a typical value of 0.15, and b has a typical value of 1.2.

7. The method of claim 4, wherein K₂ has a typical value of −0.00001, K₃ has a typical value of 0.001, K₄ has a typical value of −0.00005, and C₁ has a typical value of 0.005.

8. The method of claim 5, wherein K₅ has a typical value of 0.0001 and C₂ has a typical value of 0.02.

9. The method of claim 1, further comprising calibrating the compensation parameters by operating the meter at the rated maximum current for a duration of one hour, recording error values at one-minute intervals, and performing curve fitting for each stage to determine optimal parameters.

10. The method of claim 1, wherein, when the high-current condition interrupts, the method further comprises pausing the timer while retaining the current stage, resuming the compensation process upon re-entry into the high-current condition, and resetting the timer and restoring the original power gain value if the interruption exceeds a predefined duration.

11. An electricity meter comprising a current transformer configured to measure load current, a metering chip configured to process power gain adjustments, and a processor configured to execute the method of claim 1.
